(19) United States
(12) Patent Application Publication
(10) Pub. No.: US 2026/0268985 A1
(43) Pub. Date: Sep. 10, 2026

(54) SEMICONDUCTOR STORAGE DEVICE

(71) Applicant: Kioxia Corporation, Tokyo (JP)

(72) Inventors: Akiyuki MURAYAMA, Tokyo (JP); Shinji SUZUKI, Sagamihara (JP); Hiroyasu TANAKA, Yokohama (JP); Katsuya NISHIYAMA, Yokohama (JP)

(73) Assignee: Kioxia Corporation, Tokyo (JP)

(21) Appl. No.: 19/321,381

(22) Filed: Sep. 8, 2025

(30) Foreign Application Priority Data
Mar. 7, 2025 (JP) 2025-036769

(51) Int. Cl. G11C 16/30; G11C 16/26

(52) U.S. Cl. CPC G11C 16/30; G11C 16/26

(57) ABSTRACT

The semiconductor storage device includes a bit line, a plurality of word lines, a plurality of string units, a plurality of first selection gate lines, a dividing portion, a second selection gate line, and a third selection gate line. The string units each include a memory string including a plurality of memory cells and a plurality of selection transistors connected in series in the first direction and the string units. The first selection gate lines are divided from each other in the second direction. The dividing portion partially overlaps one of the memory strings electrically connected to the bit line and divides the first selection gate lines from each other. The second selection gate line is not divided by the dividing portion and selects odd-numbered string units. The third selection gate line is not divided by the dividing portion and selects even-numbered string units.

### CROSS REFERENCE TO RELATED APPLICATIONS

This application is based upon and claims the benefit of priority from the prior Japanese Patent Application No. 2025-36769, filed on Mar. 7, 2025, the entire contents of which are incorporated herein by reference.

### FIELD

The embodiments of the present invention relate to a semiconductor storage device.

### BACKGROUND

In a semiconductor storage device such as a three-dimensional semiconductor memory, there is a case where dividing portions that divide string units are provided to partially overlap memory strings each electrically connected to a bit line. In this case, a leakage current is liable to be generated in unselected string units.

### BRIEF DESCRIPTION OF THE DRAWINGS

FIG. 1 is a block diagram illustrating a schematic configuration of a memory system according to a first embodiment;

FIG. 2 is a block diagram illustrating a schematic configuration of a semiconductor storage device according to the first embodiment;

FIG. 3 is a sectional view illustrating a cross-section structure of the semiconductor storage device according to the first embodiment;

FIG. 4 is a sectional view illustrating a cross-section structure of a columnar part of the semiconductor storage device according to the first embodiment;

FIG. 5 is a sectional view illustrating a cross section of the semiconductor storage device according to the first embodiment along a line V-V in FIG. 4;

FIG. 6 is a sectional view illustrating a memory cell array of a single block in the semiconductor storage device according to the first embodiment;

FIG. 7 is a circuit diagram illustrating an equivalent circuit of the semiconductor storage device according to the first embodiment;

FIG. 8 is a table representing control on application of voltages to select gate lines in an operation example of the semiconductor storage device according to the first embodiment;

FIG. 9 is a diagram illustrating a distribution of threshold voltages of the memory cell array in an operation example of the semiconductor storage device according to the first embodiment;

FIG. 10 is a waveform diagram illustrating an operation example of the semiconductor storage device according to the first embodiment;

FIG. 11 is a sectional view illustrating an operation example of the semiconductor storage device according to the first embodiment;

FIG. 12 is a sectional view illustrating a memory cell array of a single block in a semiconductor storage device according to a modification of the first embodiment;

FIG. 13 is a table representing control on application of voltages to the select gate lines in an operation example of the semiconductor storage device according to the modification of the first embodiment;

FIG. 14 is a schematic diagram illustrating a semiconductor storage device according to a second embodiment;

FIG. 15 is a schematic diagram illustrating a semiconductor storage device according to a comparative example;

FIG. 16 is a schematic diagram illustrating a semiconductor storage device according to a modification of the second embodiment;

FIG. 17 is a sectional view illustrating a memory cell array of a single block in a semiconductor storage device according to a third embodiment;

FIG. 18 is a circuit diagram illustrating an equivalent circuit of the semiconductor storage device according to the third embodiment;

FIG. 19 is a table representing control on application of voltages to select gate lines in an operation example of the semiconductor storage device according to the third embodiment;

FIG. 20 is a waveform diagram illustrating an operation example of the semiconductor storage device according to the third embodiment;

FIG. 21 is a sectional view illustrating an operation example of the semiconductor storage device according to the third embodiment; and

FIG. 22 is a waveform diagram illustrating an operation example of a semiconductor storage device according to a fourth embodiment.

### DETAILED DESCRIPTION

According to one embodiment, a semiconductor storage device includes a bit line, a plurality of word lines, a plurality of string units, a plurality of first selection gate lines, a dividing portion, a second selection gate line, and a third selection gate line. The word lines are stacked in a first direction to be spaced apart from each other. The string units each include a memory string including a plurality of memory cells and a plurality of selection transistors connected in series in the first direction and the string units are adjacent to each other in a second direction. The first selection gate lines are divided from each other in the second direction. The dividing portion partially overlaps one of the memory strings electrically connected to the bit line when seen from the first direction, and divides the first selection gate lines from each other. The second selection gate line is not divided by the dividing portion and is configured to select odd-numbered string units. The third selection gate line is not divided by the dividing portion and is configured to select even-numbered string units.

Embodiments will now be explained below with reference to the drawings. For easy understanding of the explanations, the same constituent elements in the drawings are denoted by like reference signs as much as possible and redundant explanations thereof are omitted.

### First Embodiment

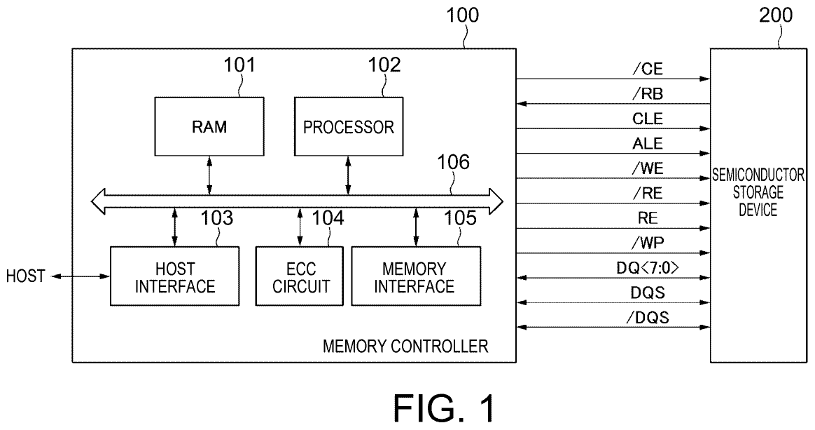

FIG. 1 is a block diagram illustrating a schematic configuration of a memory system according to a first embodiment. As illustrated in FIG. 1, the memory system according to the first embodiment includes a memory controller 100 and a semiconductor storage device 200. The semiconductor storage device 200 is a non-volatile semiconductor storage device that is constituted as a NAND flash memory. The memory system is connectable to a host. The host is, for example, an electronic device such as a personal computer or a mobile terminal. Although only one semiconductor storage device 200 is illustrated in FIG. 1, a plurality of the semiconductor storage devices 200 are arranged in a practical memory system.

The memory controller 100 controls writing of data into the semiconductor storage device 200 in accordance with a write request from the host. The memory controller 100 also controls reading of data from the semiconductor storage device 200 in accordance with a read request from the host. Signals such as a chip enable signal /CE, a ready/busy signal /RB, a command latch enable signal CLE, an address latch enable signal ALE, a write enable signal /WE, read enable signals RE and /RE, a write protect signal /WP, signals DQ<7:0> of data, and data strobe signals DQS and /DQS are transmitted and received between the memory controller 100 and the semiconductor storage device 200.

The chip enable signal /CE is a signal for enabling the semiconductor storage device 200. The ready/busy signal /RB is a signal for indicating whether the semiconductor storage device 200 is in a ready state or a busy state. The “ready state” is a state in which the semiconductor storage device 200 accepts a command from outside. The “busy state” is a state in which the semiconductor storage device 200 does not accept a command from outside. The command latch enable signal CLE is a signal indicating that the signals DQ<7:0> are a command. The address latch enable signal ALE is a signal indicating that the signals DQ<7:0> are an address. The write enable signal /WE is a signal for loading a received signal into the semiconductor storage device 200. The write enable signal /WE is asserted by the memory controller 100 each time a command, an address, and data are received. The memory controller 100 instructs the semiconductor storage device 200 to load the signals DQ<7:0> during a period in which the signal /WE is at an “L (Low)” level.

The read enable signals RE and /RE are signals for enabling the memory controller 100 to read data from the semiconductor storage device 200. The read enable signals RE and /RE are used, for example, to control an operation timing of the semiconductor storage device 200 at a time of outputting the signals DQ<7:0>. The write protect signal /WP is a signal for instructing the semiconductor storage device 200 that writing and erasing of data is inhibited. The signals DQ<7:0> are the entity of data transmitted or received between the semiconductor storage device 200 and the memory controller 100 and each include a command, an address, and data. The data strobe signals DQS and /DQS are signals for controlling input/output timings of the signals DQ<7:0>.

The memory controller 100 includes a RAM (Random Access Memory) 101, a processor 102, a host interface 103, an ECC (Error Correction Code) circuit 104, and a memory interface 105. The RAM 101, the processor 102, the host interface 103, the ECC circuit 104, and the memory interface 105 are connected to each other via an internal bus 106.

The host interface 103 outputs a request, user data (data to be written), and the like received from the host to the internal bus 106. The host interface 103 also transmits user data read from the semiconductor storage device 200, a response from the processor 102, and the like to the host.

The memory interface 105 controls processing to write user data and the like into the semiconductor storage device 200 and processing to read user data and the like from the semiconductor storage device 200, in accordance with an instruction of the processor 102. The processor 102 generally controls the memory controller 100. The processor 102 is, for example, a CPU (Central Processing Unit) or an MPU (Micro Processing Unit). When receiving a request from the host via the host interface 103, the processor 102 executes control in accordance with the request. For example, the processor 102 instructs the memory interface 105 to write user data and a parity into the semiconductor storage device 200 in accordance with a request from the host. The processor 102 instructs the memory interface 105 to read user data and a parity from the semiconductor storage device 200 in accordance with a request from the host.

The processor 102 determines a storage area (a memory area) on the semiconductor storage device 200 for user data accumulated in the RAM 101. The user data is stored in the RAM 101 via the internal bus 106. The processor 102 performs determination of the memory area for data (page data) in the unit of a page as a write unit. User data stored in one page of the semiconductor storage device 200 is hereinafter referred to also as “unit data”. Unit data is normally encoded and stored as a code word in the semiconductor storage device 200. In the present embodiment, encoding is non-essential. While the memory controller 100 may store unit data in the semiconductor storage device 200 without encoding the unit data, a configuration in which the memory controller 100 performs encoding is illustrated in FIG. 1 as one example. In a case where the memory controller 100 does not perform encoding, page data is the same as unit data. One code word may be generated based on one piece of unit data, or one code word may be generated based on divided data obtained by dividing unit data. Alternatively, one code word may be generated using plural pieces of unit data.

The processor 102 determines a memory area of the semiconductor storage device 200 as a write destination with respect to each piece of unit data. A physical address is allocated to a memory area of the semiconductor storage device 200. The processor 102 manages a memory area as a write destination of unit data using the physical address. The processor 102 instructs the memory interface 105 to write user data into the semiconductor storage device 200 while designating the determined memory area (physical address). The processor 102 manages a correspondence between logical addresses of user data (logical addresses managed by the host) and physical addresses. When receiving a read request including a logical address from the host, the processor 102 specifies a physical address corresponding to the logical address and instructs the memory interface 105 to read user data while designating the physical address.

The ECC circuit 104 encodes user data stored in the RAM 101 to generate a code word. the ECC circuit 104 also decodes a code word read from the semiconductor storage device 200. The RAM 101 temporarily stores user data received from the host before the user data is stored in the semiconductor storage device 200, or temporarily stores data read from the semiconductor storage device 200 before the data is transmitted to the host. The RAM 101 is, for example, a general-purpose memory such as an SRAM (Static RAM) or a DRAM (Dynamic RAM).

A configuration example in which the memory controller 100 includes the ECC circuit 104 and the memory interface 105 is illustrated in FIG. 1. However, the ECC circuit 104 may be incorporated in the memory interface 105. Alternatively, the ECC circuit 104 may be incorporated in the semiconductor storage device 200. Specific configurations of the components illustrated in FIG. 1 and specific arrangement thereof are not particularly limited to those in the example.

When receiving a write request from the host, the memory system illustrated in FIG. 1 operates as follows. The processor 102 temporarily stores data as a read target in the RAM 101. The processor 102 reads the data stored in the RAM 101 to input the data to the ECC circuit 104. The ECC circuit 104 encodes the input data and inputs a resultant code word to the memory interface 105. The memory interface 105 writes the input code word into the semiconductor storage device 200.

When receiving a read request from the host, the memory system illustrated in FIG. 1 operates as follows. The memory interface 105 inputs a code word read from the semiconductor storage device 200 to the ECC circuit 104. The ECC circuit 104 decodes the input code word and stores decoded data in the RAM 101. The processor 102 transmits the data stored in the RAM 101 to the host via the host interface 103.

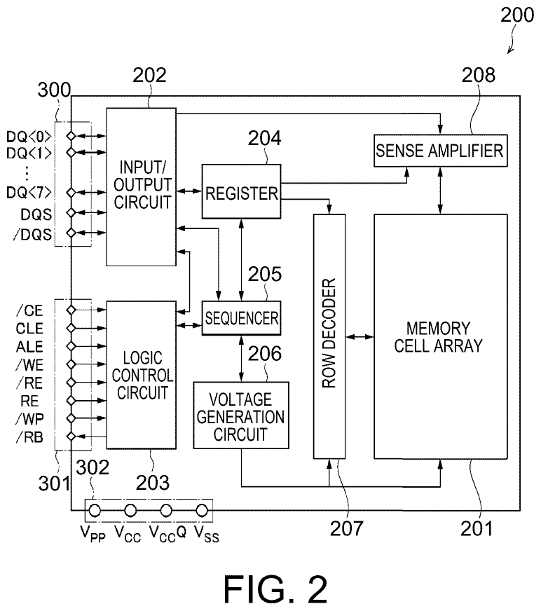

FIG. 2 is a block diagram illustrating a schematic configuration of the semiconductor storage device 200 according to the first embodiment. As illustrated in FIG. 2, the semiconductor storage device 200 includes a memory cell array 201, an input/output circuit 202, a logic control circuit 203, a register 204, a sequencer 205, a voltage generation circuit 206, a row decoder 207, a sense amplifier 208, an input/output pad group 300, a logic-control pad group 301, and a power-input terminal group 302. The sequencer 205 is an example of a control circuit.

The memory cell array 201 is a part that stores data therein. The memory cell array 201 is configured to have a plurality of memory cell transistors associated with a plurality of bit lines and a plurality of word lines. The input/output circuit 202 transmits and receives the signals DQ<7:0> and the data strobe signals DQS and /DQS to/from the memory controller 100. The input/output circuit 202 transfers a command and an address in each of the signals DQ<7:0> to the register 204. The input/output circuit 202 also transmits and receives data to be written and read data to/from the sense amplifier 208.

The logic control circuit 203 receives the chip enable signal /CE, the command latch enable signal CLE, the address latch enable signal ALE, the write enable signal /WE, the read enable signals RE and /RE, and the write protect signal /WP from the memory controller 100. The logic control circuit 203 transfers the ready/busy signal /RB to the memory controller 100 to notify the outside of the state of the semiconductor storage device 200.

The register 204 temporarily retains various types of data. For example, the register 204 retains a command instructing a write operation, a read operation, an erase operation, or the like. This command is input from the memory controller 100 to the input/output circuit 202 and is then transferred from the input/output circuit 202 to the register 204 to be retained therein. The register 204 also retains an address corresponding to the above command. This address is input from the memory controller 100 to the input/output circuit 202 and is then transferred from the input/output circuit 202 to the register 204 to be retained therein. The register 204 also retains status information indicating an operating state of the semiconductor storage device 200. The status information is updated by the sequencer 205 every time according to the operating state of the memory cell array 201 or the like. The status information is output as a state signal from the input/output circuit 202 to the memory controller 100 in response to a request from the memory controller 100.

The sequencer 205 controls operations of components including the memory cell array 201 on the basis of a control signal input from the memory controller 100 to the input/output circuit 202 and the logic control circuit 203. The voltage generation circuit 206 is a part configured to generate a necessary voltage for each of a write operation, a read operation, and an erase operation for data in the memory cell array 201. These voltages include, for example, a voltage applied to each of the word lines and the bit lines of the memory cell array 201. The operation of the voltage generation circuit 206 is controlled by the sequencer 205.

The row decoder 207 is a circuit constituted of a group of switches each applying a voltage to one of the word lines of the memory cell array 201. The row decoder 207 receives a block address and a row address from the register 204 to select a block based on the block address and select a word line based on the row address. The row decoder 207 changes open/close states of the switch group to enable a voltage from the voltage generation circuit 206 to be applied to a selected word line. The operation of the row decoder 207 is controlled by the sequencer 205.

The sense amplifier 208 is a circuit for adjusting the voltage to be applied to a bit line in the memory cell array 201 or for reading the voltage of a bit line to be converted into data. At the time of reading data, the sense amplifier 208 acquires data read from a memory cell transistor in the memory cell array 201 to a bit line and transfers the acquired read data to the input/output circuit 202. At the time of writing data, the sense amplifier 208 transfers data to be written via a bit line to a memory cell transistor. The operation of the sense amplifier 208 is controlled by the sequencer 205.

The input/output pad group 300 is a part where a plurality of terminals (pads) for performing transmission and reception of signals between the memory controller 100 and the input/output circuit 202 are provided. The terminals are individually provided to correspond to each of the signals DQ<7:0> and the data strobe signals DQS and /DQS.

The logic-control pad group 301 is a part where a plurality of terminals for performing transmission and reception of signals between the memory controller 100 and the logic control circuit 203 are provided. The terminals are individually provided to correspond to each of the chip enable signal /CE, the command latch enable signal CLE, the address latch enable signal ALE, the write enable signal /WE, the read enable signals RE and /RE, the write protect signal /WP, and the ready/busy signal /RB.

The power-input terminal group 302 is a part where a plurality of terminals for receiving application of voltages required for the operation of the semiconductor storage device 200 are provided. The voltages applied to the terminals include power-supply voltages Vcc, VccQ, and Vpp, and a ground voltage Vss. The power-supply voltage Vcc is a circuit power-supply voltage applied as operational power from outside and is, for example, a voltage of about 3.3 V. The power-supply voltage VccQ is, for example, a voltage of 1.2 V. The power-supply voltage VccQ is a voltage used when a signal is transmitted and received between the memory controller 100 and the semiconductor storage device 200. The power-supply voltage Vpp is a power-supply voltage higher than the power-supply voltage Vcc and is, for example, a voltage of 12 V.

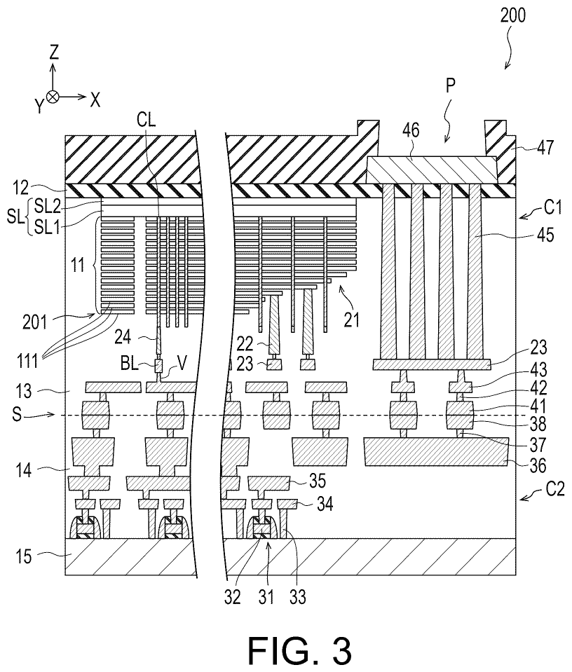

FIG. 3 is a sectional view illustrating a cross-section structure of the semiconductor storage device 200 according to the first embodiment. A structure of the semiconductor storage device 200, particularly a structure near the memory cell array 201 is specifically described next with reference to FIG. 3. As illustrated in FIG. 3, the semiconductor storage device 200 is a three-dimensional memory obtained by bonding an array chip C1 having the memory cell array 201, and a circuit chip C2 having a peripheral circuit to each other. The peripheral circuit includes the sense amplifier 208 and the row decoder 207 illustrated in FIG. 2, and the like. The array chip C1 and the circuit chip C2 are bonded to each other on a bonding face S. That is, the array chip C1 and the circuit chip C2 are electrically connected to each other via lines joined on the bonding face S. Therefore, the semiconductor storage device 200 of the first embodiment has a CBA (CMOS directly Bonded to Array) structure.

The circuit chip C2 includes a substrate 15, a plurality of transistors 31, a plurality of contact plugs 33, wiring layers 34, 35, and 36, a plurality of via plugs 37, a plurality of metal pads 38, and an interlayer dielectric film 14. Hereinafter, directions parallel to the surface of the substrate 15, that is, the upper surface thereof and perpendicular to each other are defined as an X direction and a Y direction. A direction perpendicular to the surface of the substrate 15 is defined as a Z direction. The Z direction is an example of a first direction.

The substrate 15 is, for example, a semiconductor substrate such as a silicon substrate. The transistors 31 constitute CMOS circuits. Each of the transistors 31 includes a gate electrode 32 provided on the substrate 15 with a gate dielectric film interposed therebetween, and a source diffused layer and a drain diffused layer (not illustrated) provided in the substrate 15. Semiconductor elements such as a resistive element and a capacitive element may be formed on the substrate 15, in addition to the transistors 31.

Each of the contact plugs 33 is arranged on the source diffused layer or the drain diffused layer of the corresponding transistor 31.

The wiring layer 34 is arranged on the contact plugs 33. The wiring layer 34 includes a plurality of lines connected to the corresponding contact plugs 33. The wiring layer 35 is arranged on the wiring layer 34. The wiring layer 35 includes a plurality of lines connected to the corresponding lines of the wiring layer 34. The wiring layer 36 is arranged on the wiring layer 35. The wiring layer 36 includes a plurality of lines connected to the corresponding lines of the wiring layer 35.

The via plugs 37 are arranged on the corresponding lines of the wiring layer 36. The metal pads 38 are arranged on the corresponding via plugs 37. The wiring layers 34 to 36, the via plugs 37, and the metal pads 38 may be formed of, for example, a low-resistance metal such as copper or tungsten. The interlayer dielectric film 14 coats and protects the transistors 31, the contact plugs 33, the wiring layers 34 to 36, the via plugs 37, and the metal pads 38. The interlayer dielectric film 14 is, for example, a silicon oxide (SiOₓ) film.

The array chip C1 includes stacked films 11, columnar parts CL, a source line SL, an interlayer dielectric film 13, and an insulating film 12.

The stacked films 11 are arranged above the transistors 31 of the circuit chip C2. That is, the stacked films 11 are located in the Z direction with respect to the substrate 15. The stacked films 11 are configured by alternately stacking a plurality of conductive layers 111 and a plurality of insulating layers (not illustrated) in the Z direction. A plurality of the conductive layers 111 on an end side in the +Z direction (an upper end side in FIG. 3) of the stacked films 11 function as source-side select gate lines SGS. A plurality of the conductive layers 111 on an end side in the −Z direction (a lower end side in FIG. 3) of the stacked films 11 function as drain-side select gate lines SGD. Conductive layers 111 located between the source-side select gate lines SGS and the drain-side select gate lines SGD function as word lines WL. Bit lines BL are located below the stacked films 11. The bit lines BL are formed to extend in the Y direction. In FIG. 3, one bit line BL is representatively illustrated. Practically, a plurality of bit lines BL are arranged to be spaced from each other in the X direction.

A stepped structure portion 21 is arranged at each end part of the stacked films 11 in the X direction. Portions functioning as the word lines WL in the stacked films 11 are electrically connected to a wiring layer 23 with contacts 22. The source line SL is arranged above the stacked films 11 with an insulating film interposed therebetween. The source line SL has a lower layer SL1 and an upper layer SL2. The lower layer SL1 is formed of, for example, a semiconductor material such as silicon. The upper layer SL2 is formed of, for example, a metallic material such as tungsten.

The columnar parts CL are arranged in the stacked films 11 to penetrate therethrough in the Z direction. A lower end portion of each of the columnar parts CL is electrically connected to a bit line BL with a via plug 24. The bit lines BL are included in the wiring layer 23. Upper end portions of the columnar parts CL are electrically connected to the source line SL. A wiring layer 43 including via plugs V is arranged below the wiring layer 23. Via plugs 42 are arranged below the wiring layer 43. A plurality of metal pads 41 are arranged below the via plugs 42. The via plugs 24 and 42, the wiring layers 23 and 43, and the metal pads 41 are formed of, for example, a low-resistance metal such as copper or tungsten.

The insulating film 12 is arranged above the stacked films 11. The insulating film 12 is, for example, a silicon oxide film or a silicon nitride (SiN) film. Via plugs 45 are arranged in a portion of the array chip C1 away in the X direction from the stacked films 11. The via plugs 45 are formed to extend upward from the wiring layer 23. Metal pads 46 are arranged on the upper surface of the insulating film 12. Upper end portions of the via plugs 45 penetrate through the insulating film 12 to be electrically connected to the metal pads 46. The metal pads 46 are, for example, a metallic film containing copper. The metal pads 46 function as external connection pads of the semiconductor storage device 200. A passivation film 47 is further arranged on the upper surface of the insulating film 12 to expose the metal pads 46. The passivation film 47 is, for example, a silicon oxide film. The passivation film 47 has openings P to expose the upper surfaces of the metal pads 46. The metal pads 46 can be connected to a mounting board or other devices with a bonding wire or the like through the openings P.

The interlayer dielectric film 13 of the array chip C1 and the interlayer dielectric film 14 of the circuit chip C2 are bonded to each other on the bonding face S. The metal pads 41 of the array chip C1 and the metal pads 38 of the circuit chip C2 are bonded to each other on the bonding face S. Accordingly, the array chip C1 and the circuit chip 2 are electrically connected to each other with the metal pads 38 and 41.

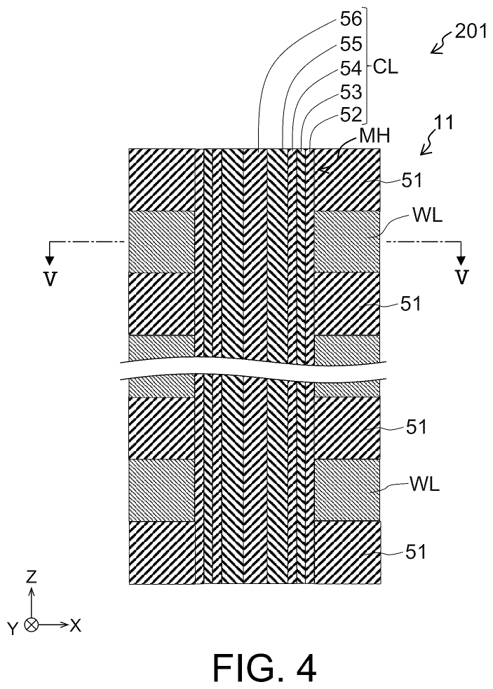

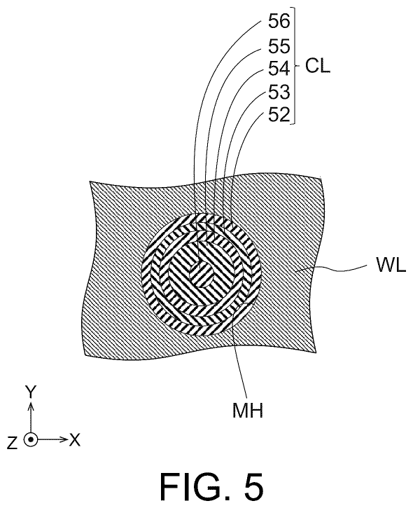

FIG. 4 is a sectional view illustrating a cross-section structure of a columnar part CL of the semiconductor storage device 200 according to the first embodiment. FIG. 5 is a sectional view illustrating a cross section of the semiconductor storage device 200 according to the first embodiment along a line V-V in FIG. 4.

As illustrated in FIG. 4, the memory cell array 201 includes a plurality of word lines WL and a plurality of insulating layers 51 alternately stacked on the interlayer dielectric film 13 (FIG. 3). That is, the memory cell array 201 includes the stacked films 11 obtained by alternately and repeatedly stacking the word lines WL and the insulating layers 51. The word lines WL include, for example, tungsten (W) as a primary component. The word lines WL may include transition elements such as molybdenum (Mo), titanium (Ti), and niobium (Nb) other than tungsten. The insulating layers 51 are mainly constituted of silicon oxide (SiO₂).

Each of the columnar parts CL is arranged in the stacked films 11 to penetrate therethrough in the Z direction. That is, each of the columnar parts CL is arranged inside of a memory hole MH penetrating through the stacked films 11 in the Z direction. In an example illustrated in FIG. 5, a transverse section of the columnar part CL has a circular shape. The columnar part CL includes a block dielectric film 52, a charge accumulating film 53, a tunnel dielectric film 54, a channel semiconductor film 55, and a core dielectric film 56 in this order. The charge accumulating film 53 is, for example, a silicon nitride film. The charge accumulating film 53 is formed on the side surfaces of the word lines WL and the insulating layers 51 with the block dielectric film 52 interposed therebetween. The charge accumulating film 53 may be a semiconductor layer such as a polysilicon layer. The channel semiconductor film 55 is, for example, a polysilicon layer. The channel semiconductor film 55 is formed on the side surface of the charge accumulating film 53 with the tunnel dielectric film 54 interposed therebetween. The block dielectric film 52, the tunnel dielectric film 54, and the core dielectric film 56 are, for example, silicon oxide films or metallic insulating films.

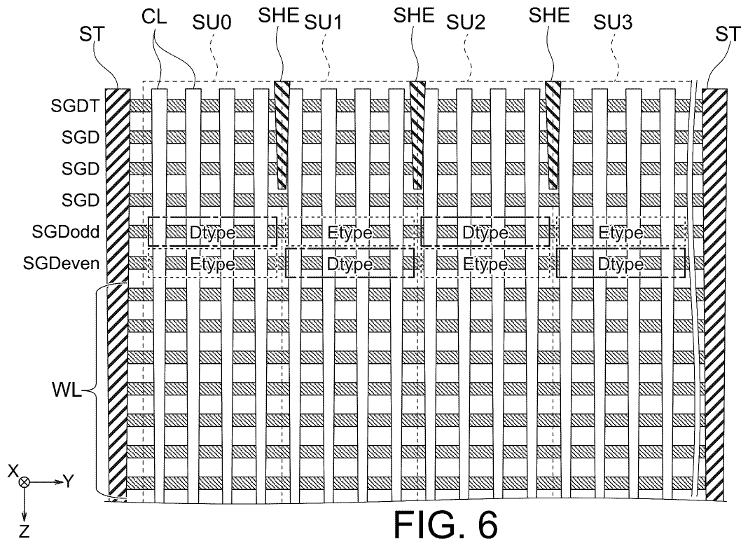

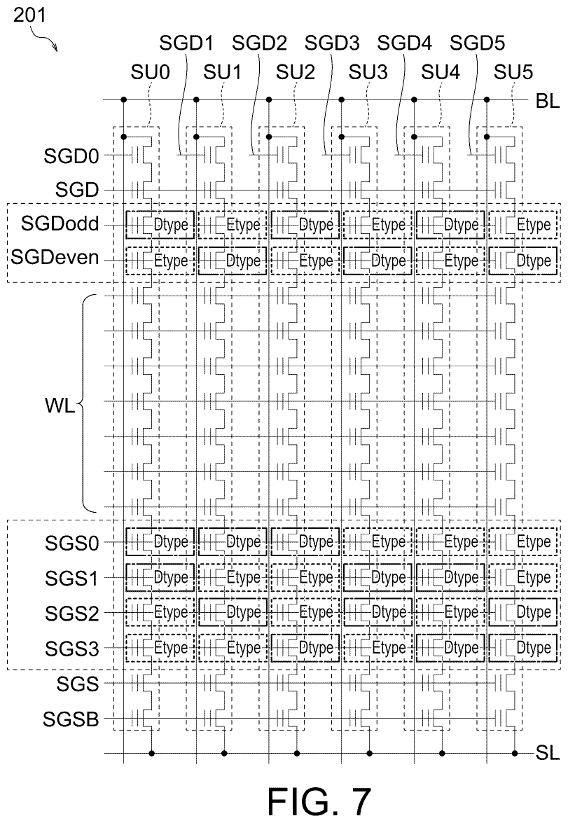

FIG. 6 is a sectional view illustrating the memory cell array 201 of a single block in the semiconductor storage device 200 according to the first embodiment. FIG. 7 is a circuit diagram illustrating an equivalent circuit of the semiconductor storage device 200 according to the first embodiment.

As illustrated in FIG. 6, the memory cell array 201 of a single block defined by insulating layers ST that divide the stacked films 11 includes a plurality of string units SU0 to SU3 . . . , a plurality of layers of drain-side select gate lines SGDT, SGD, SGDodd, and SGDeven, and a plurality of dividing portions SHE. The insulating layers ST and the dividing portions SHE extend in the X direction in FIG. 6. The drain-side select gate line SGDT is one example of a fourth selection gate line. The drain-side select gate lines SGD are one example of a first selection gate line. The drain-side select gate line SGDodd is one example of a second selection gate line. The drain-side select gate line SGDeven is one example of a third selection gate line.

As illustrated in FIG. 7, the memory cell array 201 of a single block further includes a plurality of source-side select gate lines SGS0, SGS1, SGS2, SGS3, SGS, and SGSB on the opposite side of the word lines WL to the drain-side select gate lines SGDT, SGD, SGDodd, and SGDeven. The source-side select gate lines SGS0 to SGS3 are examples of a fifth selection gate line.

The string units SU0 to SU3 . . . are adjacent to each other in the Y direction. In the examples illustrated in FIGS. 6 and 7, a first string unit SU0 positioned first in the Y direction from one end of a single block, a third string unit SU2 positioned third, and a fifth string SU4 positioned fifth are examples of an odd-numbered string unit. A second string unit SU1 positioned second in the Y direction from the end of the single block, a fourth string unit SU3 positioned fourth, and a sixth string unit SU5 positioned sixth are examples of an even-numbered string unit.

The plural layers of the drain-side select gate lines SGD are configured to be stacked in an upper part in FIG. 6 (that is, in the −Z direction) with the insulating layer 51 (see FIG. 4) interposed therebetween. In FIG. 6, illustrations of the insulating layers 51 are omitted. Two or more layers of the drain-side select gate lines SGD on an upper layer side in FIG. 6 among the plural layers of the drain-side select gate lines SGD are divided in the Y direction by the dividing portions SHE into a plurality of drain-side select gate lines SGD (that is, drain-side select gate lines SGD each corresponding to a string unit). In FIG. 7, reference signs SGD0, SGD1, SGD2, SGD3, SGD4, and SGD5 representatively denote the plural layers of the drain-side select gate lines SGD and SGDT divided by the dividing portions SHE.

The drain-side select gate line SGDT is arranged in an upper layer (in the −Z direction) than the drain-side select gate lines SGD in FIG. 6. The drain-side select gate line SGDT generates a GIDL (gate induced drain leakage) current for an erase operation. The drain-side select gate line SGDT is divided in the Y direction by the dividing portions SHE into a plurality of drain-side select gate lines SGDT (that is, drain-side select gate lines SGDT each corresponding to a string unit).

Each of the dividing portions SHE partially overlaps a memory string (that is, a columnar part CL) electrically connected to a bit line BL when seen from the Z direction. In other words, a memory string partially overlapping a dividing portion SHE is not a dummy memory string not electrically connected to a bit line BL. In still other words, the semiconductor storage device 200 does not have dummy memory strings overlapping the dividing portions SHE. Due to not having dummy memory strings, the memory density can be increased.

The dividing portions SHE are provided spaced apart from each other in the Y direction to divide each of the drain-side select gate lines SGD and SGDT in the Y direction into a plurality of drain-side select gate lines SGD and SGDT. The dividing portions SHE are located at boundary positions of the string units SU0 to SU3 . . . , respectively. Each of the dividing portions SHE is constituted of an insulating film. The insulating film constituting each of the dividing portions SHE may be a silicon oxide film.

The drain-side select gate line SGDodd is arranged in a lower layer (in the Z direction) than the drain-side select gate lines SGD in FIG. 6. In the examples illustrated in FIGS. 6 and 7, only one layer of the drain-side select gate line SGDodd is arranged. The drain-side select gate line SGDodd selects odd-numbered string units. In the examples illustrated in FIGS. 6 and 7, the drain-side select gate line SGDodd selects the first string unit SU0, the third string unit SU2, and the fifth string unit SU4. The drain-side select gate line SGDodd is not divided by the dividing portions SHE. In the example illustrated in FIG. 6, the drain-side select gate line SGDodd is not divided by the dividing portions SHE because being arranged away downward from the dividing portions SHE.

The drain-side select gate line SGDeven is arranged in a lower layer than the drain-side select gate line SGDodd in FIG. 6. In the examples illustrated in FIGS. 6 and 7, only one layer of the drain-side select gate line SGDeven is arranged. The drain-side select gate line SGDeven selects even-numbered string units. In the examples illustrated in FIGS. 6 and 7, the drain-side select gate line SGDeven selects the second string unit SU1, the fourth string unit SU3, and the sixth string unit SU5. The drain-side select gate line SGDeven is not divided by the dividing portions SHE. In the example illustrated in FIG. 6, the drain-side select gate line SGDeven is not divided by the dividing portions SHE because being arranged away downward from the dividing portions SHE.

Each of the odd-numbered string units SU0, SU2, and SU4 includes depletion-type select transistors Dtype (that is, first selection transistors) selected by the drain-side select gate line SGDodd. In FIG. 6, the depletion-type select transistors each included in each of the memory strings included in one odd-numbered string unit are collectively represented as “Dtype”. Each of the odd-numbered string units SU0, SU2, and SU4 further includes enhancement-type select transistors Etype (that is, second selection transistors) selected by the drain-side select gate line SGDeven. In FIG. 6, the enhancement-type select transistors each included in each of the memory strings included in one odd-numbered string unit are collectively represented as “Etype”.

When an even-numbered string unit SU1, SU3, or SU5 is selected by the drain-side select gate line SGDeven, the enhancement-type select transistors Etype of the odd-numbered string units SU0, SU2, and SU4 are turned off. Accordingly, it is possible to suppress a leakage current caused by overlap of the dividing portions SHE with memory strings from flowing into the odd-numbered string units SU0, SU2, and SU4 when an even-numbered string unit SU1, SU3, or SU5 is selected.

Each of the even-numbered string units SU1, SU3, and SU5 includes enhancement-type select transistors Etype (that is, third selection transistors) selected by the drain-side select gate line SGDodd. In FIG. 6, the enhancement-type select transistors each included in each of the memory strings included in one even-numbered string unit are collectively represented as “Etype”. Each of the even-numbered string units SU1, SU3, and SU5 further includes depletion-type select transistors Dtype (that is, fourth selection transistors) selected by the drain-side select gate line SGDeven. In FIG. 6, the depletion-type select transistors each included in each of the memory strings included in one odd-numbered string unit are collectively represented as “Dtype”.

When an odd-numbered string unit SU0, SU2, or SU4 is selected by the drain-side select gate line SGDodd, the enhancement-type select transistors Etype of the even-numbered string units SU1, SU3, and SU5 are turned off. Accordingly, it is possible to suppress a leakage current caused by overlap of the dividing portions SHE with memory strings from flowing into the even-numbered string units SU1, SU3, and SU5 when an odd-numbered string unit SU0, SU2, or SU4 is selected.

In the example illustrated in FIG. 7, each of the odd-numbered string units SU0, SU2, and SU4 has select transistors (that is, fifth selection transistors) selected by the source-side select gate lines SGS0 to SGS3. Each of the even-numbered string units SU1, SU3, and SU5 has select transistors (that is, sixth selection transistors) selected by the source-side select gate lines SGS0 to SGS3.

Specifically, the first string unit SU0 includes depletion-type select transistors Dtype selected by the source-side select gate lines SGS0 and SGS1, and enhancement-type select transistors Etype selected by the source-side select gate lines SGS2 and SGS3. The second string unit SU1 includes depletion-type select transistors Dtype selected by the source-side select gate lines SGS0 and SGS2, and enhancement-type select transistors Etype selected by the source-side select gate lines SGS1 and SGS3. The third string unit SU2 includes depletion-type select transistors Dtype selected by the source-side select gate lines SGS0 and SGS3, and enhancement-type select transistors Etype selected by the source-side select gate lines SGS1 and SGS2. The fourth string unit SU3 includes depletion-type select transistors Dtype selected by the source-side select gate lines SGS1 and SGS2, and enhancement-type select transistors Etype selected by the source-side select gate lines SGS0 and SGS3. The fifth string unit SU4 includes depletion-type select transistors Dtype selected by the source-side select gate lines SGS1 and SGS3, and enhancement-type select transistors Etype selected by the source-side select gate lines SGS0 and SGS2. The sixth string unit SU5 includes depletion-type select transistors Dtype selected by the source-side select gate lines SGS2 and SGS3, and enhancement-type select transistors Etype selected by the source-side select gate lines SGS0 and SGS1.

With the select transistors selected by the source-side select gate lines SGS0 to SGS3, any one of the string units SU0 to SU5 can be selected in a single block according to a combination of voltages applied to the source-side select gate lines SGS0 to SGS3.

The sequencer 205 controls application of voltages to the select transistors Etype and Dtype. Threshold voltages of the enhancement-type select transistors Etype of the string units may be equal to each other. Threshold voltages of the depletion-type select transistors Dtype of the string units may be equal to each other.

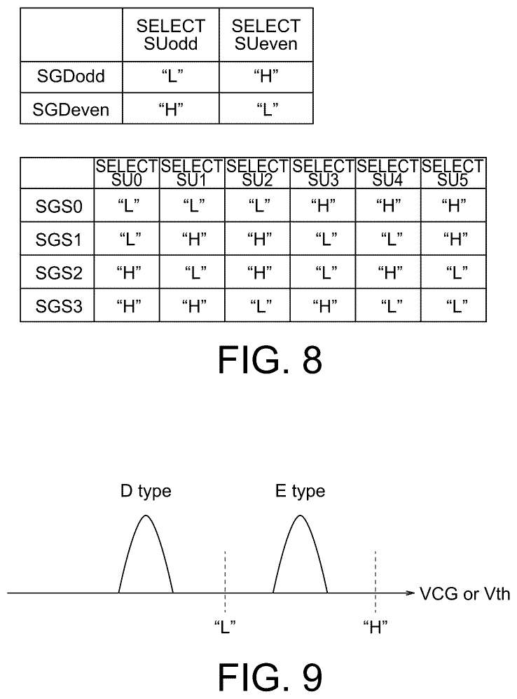

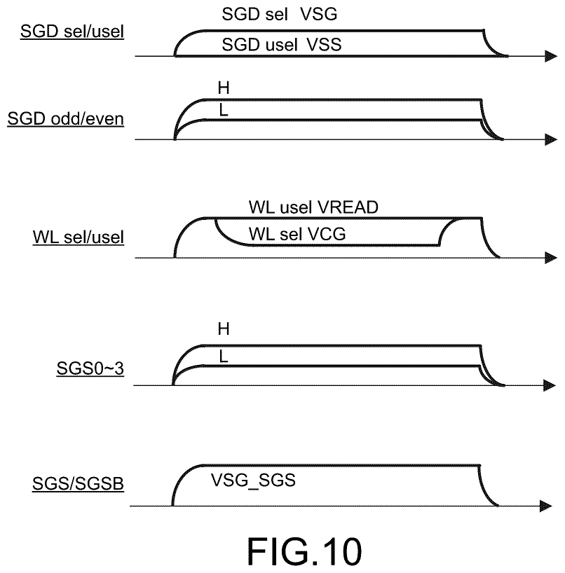

An operation example of the semiconductor storage device 200 is described next. FIG. 8 is a table representing control on application of voltages to the select gate lines in an operation example of the semiconductor storage device 200 according to the first embodiment. FIG. 9 is a diagram illustrating a distribution of threshold voltages Vth of the memory cell array in an operation example of the semiconductor storage device 200 according to the first embodiment. In FIG. 9, a reference sign “Dtype” denotes the threshold voltage of the depletion-type select transistors Dtype. Reference sign “Etype” denotes the threshold voltage of the enhancement-type select transistors Etype. FIG. 10 is a waveform diagram illustrating an operation example of the semiconductor storage device 200 according to the first embodiment.

The sequencer 205 controls the operation of the semiconductor storage device 200 in accordance with the table illustrated in FIG. 8. When a read operation for memory cells in an odd-numbered string unit SU0, SU2, or SU4 is to be performed, the sequencer 205 applies a selection voltage (VSG in FIG. 10) to the drain-side select gate line SGD of any one of the odd-numbered string units SU0, SU2, and SU4. The sequencer 205 also applies a non-selection voltage (VSS in FIG. 10, that is, the ground voltage) to the drain-side select gate lines SGD of unselected odd-numbered string units SU0, SU2, or SU4. In FIG. 10, SGDsel represents a selected drain-side select gate line SGD. SGDusel represents an unselected drain-side select gate line SGD.

When a read operation for memory cells in an odd-numbered string unit SU0, SU2, or SU4 is to be performed, the sequencer 205 applies the non-selection voltage (VSS in FIG. 10, that is, the ground voltage) to the drain-side select gate lines SGD of the even-numbered string units SU1, SU3, and SU5.

When a read operation for memory cells in an odd-numbered string unit SU0, SU2, or SU4 is to be performed, the sequencer 205 applies a voltage L of a first level higher than the threshold voltage of the select transistors Dtype (that is, the first selection transistors) of the odd-numbered string units SU0, SU2, and SU4 and lower than the threshold voltage of the select transistors Etype (that is, the third selection transistors) of the even-numbered string units SU1, SU3, and SU5 to the drain-side select gate line SGDodd.

When a read operation for memory cells in an odd-numbered string unit SU0, SU2, or SU4 is to be performed, the sequencer 205 applies a voltage H of a second level higher than the threshold voltage of the select transistors Etype (that is, the second selection transistors) of the odd-numbered string units SU0, SU2, and SU4 and the threshold voltage of the select transistors Dtype (that is, the fourth selection transistors) of the even-numbered string units SU1, SU3, and SU5 to the drain-side select gate line SGDeven.

When a read operation for memory cells in an odd-numbered string unit SU0, SU2, or SU4 is to be performed, the sequencer 205 applies a voltage L of a first level for turning on the depletion-type select transistors Dtype or a voltage H of a second level for turning on both the enhancement-type select transistors Etype and the depletion-type select transistors Dtype to the source-side select gate lines SGS0 to SGS3 in accordance with items of select SU0, select SU2, and select SU4 in the table of FIG. 8. According to the table of FIG. 8, any one of the odd-numbered string units SU0, SU2, and SU4 is selected by the source-side select gate lines SGS0 to SGS3. The selected odd-numbered string unit SU0, SU2, or SU4 is electrically connected to the source line SL. The unselected string units SU0, SU2, or SU4 are brought to a floating state due to turning-off of any of the select gate lines, thereby decreasing charging load between the word lines WL and the memory cells. With a decrease in the charging load, power consumption at the time of a read operation for memory cells in an odd-numbered string unit SU0, SU2, or SU4 can be reduced. As illustrated in FIG. 10, the selection voltage (VSS) is applied to the source-side select gate lines SGS and SGSB in lower layers than the source-side select gate lines SGS0 to SGS3.

When a read operation for memory cells in an odd-numbered string unit SU0, SU2, or SU4 is to be performed, the sequencer 205 applies a voltage (VCG in FIG. 10) for turning off a memory transistor where the threshold voltage has risen and turning on a memory transistor where the threshold voltage has not risen to a selected word line WLsel.

When a read operation for memory cells in an odd-numbered string unit SU0, SU2, or SU4 is to be performed, the sequencer 205 applies a voltage (VREAD in FIG. 10) for turning on a memory transistor to unselected word lines WLusel regardless of the state of the threshold voltage. VREAD is a voltage higher than VCG.

Meanwhile, when a read operation for memory cells in an even-numbered string unit SU1, SU3, or SU5 is to be performed, the sequencer 205 applies a selection voltage (VSG in FIG. 10) to the drain-side select gate line SGD of any one of the even-numbered string units SU1, SU3, and SU5. The sequencer 205 also applies the non-selection voltage (VSS in FIG. 10, that is, the ground voltage) to the drain-side select gate lines SGD of unselected even-numbered String Units SU1, SU3, or SU5.

When a read operation for memory cells in an even-numbered string unit SU1, SU3, or SU5 is to be performed, the sequencer 205 applies the non-selection voltage (VSS in FIG. 10) to the drain-side select gate lines SGD of the odd-numbered string units SU0, SU2, and SU4.

When a read operation for memory cells in an even-numbered string unit SU1, SU3, or SU5 is to be performed, the sequencer 205 applies a voltage H of a second level higher than the threshold voltage of the select transistors Dtype (that is, the first selection transistors) of the odd-numbered string units SU0, SU2, and SU4 and the threshold voltage of the select transistors Etype (that is, the third selection transistors) of the even-numbered string units SU1, SU3, and SU5 to the drain-side select gate line SGDodd.

When a read operation for memory cells in an even-numbered string unit SU1, SU3, or SU5 is to be performed, the sequencer 205 applies a voltage L of a first level higher than the threshold voltage of the select transistors Dtype (that is, the fourth selection transistors) of the even-numbered string units SU1, SU3, and SU5 and lower than the threshold voltage of the select transistors Etype (that is, the second selection transistors) of the odd-numbered string units SU0, SU2, and SU4 to the drain-Side select gate line SGDeven.

When a read operation for memory cells in an even-numbered string unit SU1, SU3, or SU5 is to be performed, the sequencer 205 applies a voltage L of a first level for turning on the depletion-type select transistors Dtype or a voltage H of a second level for turning on both the enhancement-type select transistors Etype and the depletion-type select transistors Dtype to the source-side select gate lines SGS0 to SGS3 in accordance with items of select SU1, select SU3, and select SU5 in the table of FIG. 8. According to the table of FIG. 8, any one of the even-numbered string units SU1, SU3, and SU5 is selected by the source-side select gate lines SGS0 to SGS3. The selected even-numbered string unit SU1, SU3, or SU5 is electrically connected to the source line SL. The unselected string units SU1, SU3, or SU5 are brought to a floating state due to turning-off of any of the select gate lines, thereby decreasing charging load between the word lines WL and the memory cells. With a decrease in the charging load, power consumption at the time of a read operation for memory cells in an even-numbered string unit SU1, SU3, or SU5 can be reduced.

When a read operation for memory cells in an even-numbered string unit SU1, SU3, or SU5 is to be performed, the sequencer 205 applies the voltage (VCG in FIG. 10) for turning off a memory transistor where the threshold voltage has risen and turning on a memory transistor where the threshold voltage has not risen to a selected word line WLsel.

When a read operation for memory cells in an even-numbered string unit SU1, SU3, or SU5 is to be performed, the sequencer 205 applies the voltage (VREAD in FIG. 10) for turning on a memory transistor to unselected word lines WLusel regardless of the state of the threshold voltage.

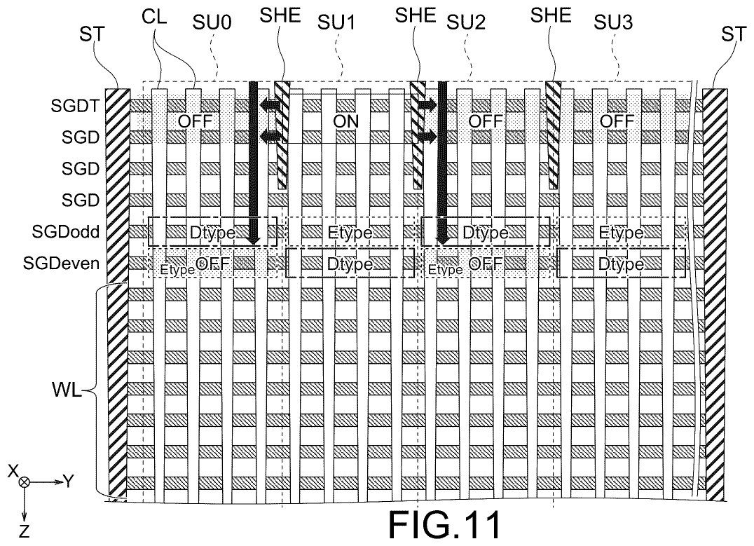

FIG. 11 is a sectional view illustrating an operation example of the semiconductor storage device 200 according to the first embodiment. As described above, each of the dividing portions SHE partially overlaps a memory string electrically connected to a bit line BL to increase the memory density.

If the semiconductor storage device 200 does not include the drain-side select gate lines SGDodd and SGDeven that are not divided by the dividing portions SHE, there is a risk that a leakage current flows from the dividing portions SHE into the even-numbered string units SU1, SU3, or SU5 when an odd-numbered string unit SU0, SU2, or SU4 is selected. There is also a risk that a leakage current flows from the dividing portions SHE into the odd-numbered string units SU0, SU2, or SU4 when an even-numbered string unit SU1, SU3, or SU5 is selected.

In contrast thereto, according to the first embodiment, the drain-side select gate lines SGDodd and SGDeven can suppress a leakage current from flowing from the dividing portions SHE into the even-numbered string units SU1, SU3, or SU5 when an odd-numbered string unit SU0, SU2, or SU4 is selected. It is also possible to suppress a leakage current from flowing from the dividing portions SHE into the odd-numbered string units SU0, SU2, or SU4 when an even-numbered string unit SU1, SU3, or SU5 is selected. According to the example illustrated in FIG. 11, when the second string unit SU1 is selected, the voltage L of the first level is applied to the drain-side select gate lines SGDeven of the first string unit SU0 and the third string unit SU2, whereby the select transistors Etype of the first string unit SU0 and the third string unit SU2 are turned off. With turning-off of the select transistors Etype, a leakage current represented by thick line arrows in FIG. 11 can be blocked.

As described above, the semiconductor storage device 200 according to the first embodiment includes one layer of the drain-side select gate line SGDodd that is not divided by the dividing portions SHE and that selects the odd-numbered string units SU0, SU2, and SU4. The semiconductor storage device 200 also includes one layer of the drain-side select gate line SGDeven that is not divided by the dividing portions SHE and that selects the even-numbered string units SU1, SU3, and SU5. This enables a leakage current caused by overlap of the dividing portions SHE with memory strings to be suppressed with a minimum necessary structure. That is, the leakage current can be suppressed at a low cost.

According to the first embodiment, each of the odd-numbered string units SU0, SU2, and SU4 has the depletion-type select transistor Dtype selected by the drain-side select gate line SGDodd, and the enhancement-type select transistor Etype selected by the drain-side select gate line SGDeven. Each of the even-numbered string units SU1, SU3, and SU5 has the enhancement-type select transistor Etype selected by the drain-side select gate line SGDodd, and the depletion-type select transistor Dtype selected by the drain-side select gate line SGDeven. With execution of the control on application of voltages represented in the table of FIG. 8 to the select transistors arranged in this manner, when one string unit is selected, adjacent string units can be turned off easily and appropriately. Accordingly, a leakage current can be suppressed easily and appropriately.

### Modification

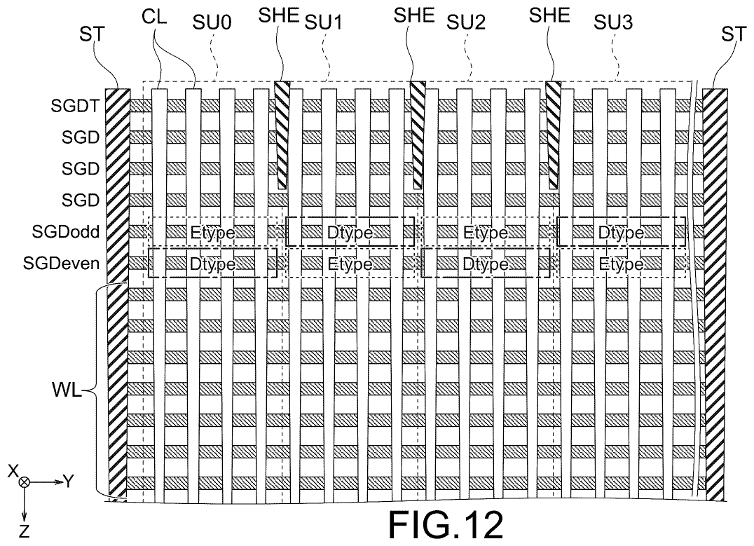

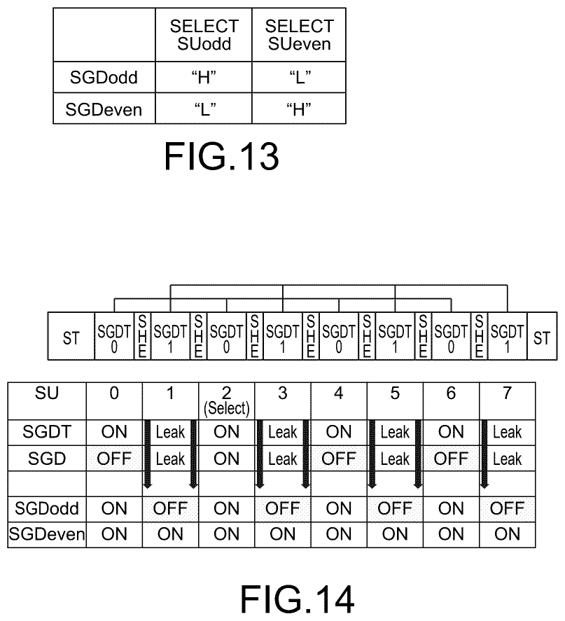

A modification of the first embodiment in which the magnitude relation among the threshold voltages of the select transistors and the magnitude relation among the voltages applied thereto are opposite to those in the embodiment described above is described next focused on differences from the embodiment described above. FIG. 12 is a sectional view illustrating a memory cell array of a single block in a semiconductor storage device 200 according to the modification of the first embodiment. FIG. 13 is a table representing control on application of voltages to the select gate lines in an operation example of the semiconductor storage device 200 according to the modification of the first embodiment.

In the example illustrated in FIG. 12, each of the odd-numbered string units SU0, SU2, and SU4 includes enhancement-type select transistors Etype (that is, seventh selection transistors) selected by the drain-side select gate line SGDodd. Each of the odd-numbered string units SU0, SU2, and SU4 further includes depletion-type select transistors Dtype (that is, eighth selection transistors) selected by the drain-side select gate line SGDeven.

In the example illustrated in FIG. 12, each of the even-numbered string units SU1, SU3, and SU5 includes depletion-type select transistors Dtype (that is, ninth selection transistors) selected by the drain-side select gate line SGDodd. Each of the even-numbered string units SU1, SU3, and SU5 further includes enhancement-type select transistors Etype (that is, tenth selection transistors) selected by the drain-side select gate line SGDeven.

In an example illustrated in FIG. 13, when a read operation for memory cells in an odd-numbered string unit SU0, SU2, or SU4 is to be performed, the sequencer 205 (that is, a second control circuit) applies a voltage H of a second level higher than the threshold voltage of the select transistors Etype of the odd-numbered string units SU0, SU2, and SU4 and the threshold voltage of the select transistors Dtype of the even-numbered string units SU1, SU3, and SU5 to the drain-side select gate line SGDodd.

When a read operation for memory cells in an odd-numbered string unit SU0, SU2, or SU4 is to be performed, the sequencer 205 applies a voltage L of a first level higher than the threshold voltage of the select transistors Dtype of the odd-numbered string units SU0, SU2, and SU4 and lower than the threshold voltage of the select transistors Etype of the even-numbered string units SU1, SU3, and SU5 to the drain-side select gate line SGDeven.

Meanwhile, when a read operation for memory cells in an even-numbered string unit SU1, SU3, or SU5 is to be performed, the sequencer 205 applies a voltage L of a first level higher than the threshold voltage of the select transistors Dtype of the even-numbered string units SU1, SU3, and SU5 and lower than the threshold voltage of the select transistors Etype of the odd-numbered string units SU0, SU2, and SU4 to the drain-side select gate line SGDodd.

When a read operation for memory cells in an even-numbered string unit SU1, SU3, or SU5 is to be performed, the sequencer 205 applies a voltage H of a second level higher than the threshold voltage of the select transistors Etype of the even-numbered string units SU1, SU3, and SU5 and the threshold voltage of the select transistors Dtype of the odd-numbered string units SU0, SU2, and SU4 to the drain-side select gate line SGDeven.

According to the examples illustrated in FIGS. 12 and 13, similarly to the embodiment described above, it is possible to suppress a leakage current from flowing from the dividing portions SHE into the even-numbered string units SU1, SU3, or SU5 when an odd-numbered string unit SU0, SU2, or SU4 is selected. It is also possible to suppress a leakage current from flowing from the dividing portions SHE into the odd-numbered string units SU0, SU2, or SU4 when an even-numbered string unit SU1, SU3, or SU5 is selected.

### Second Embodiment

A second embodiment in which control on application of a voltage to the drain-side select gate line SGDT that generates a GIDL current for an erase operation is executed collectively for even-numbered string units or odd-numbered string units is described next focused on differences from the embodiment described above.

FIG. 14 is a schematic diagram illustrating a semiconductor storage device 200 according to the second embodiment. In the second embodiment, the sequencer 205 executes control to simultaneously apply the same voltage to drain-side select gate lines SGDT0 of a plurality of odd-numbered string units SU0, SU2, SU4, and SU6. In other words, the drain-side select gate lines SGDT0 of the odd-numbered string units SU0, SU2, SU4, and SU6 are connected in parallel to each other via a line. The sequencer 205 executes control to simultaneously apply the same voltage to drain-side select gate lines SGDT1 of a plurality of even-numbered string units SU1, SU3, and SU5. In other words, the drain-side select gate lines SGDT1 of the even-numbered string units SU1, SU3, and SU5 are connected in parallel to each other via a line. Accordingly, as illustrated in FIG. 14, when one string unit SU2 is selected, generation of a leakage current in all other string units SU0 to SU1 and SU3 to SU7 can be suppressed.

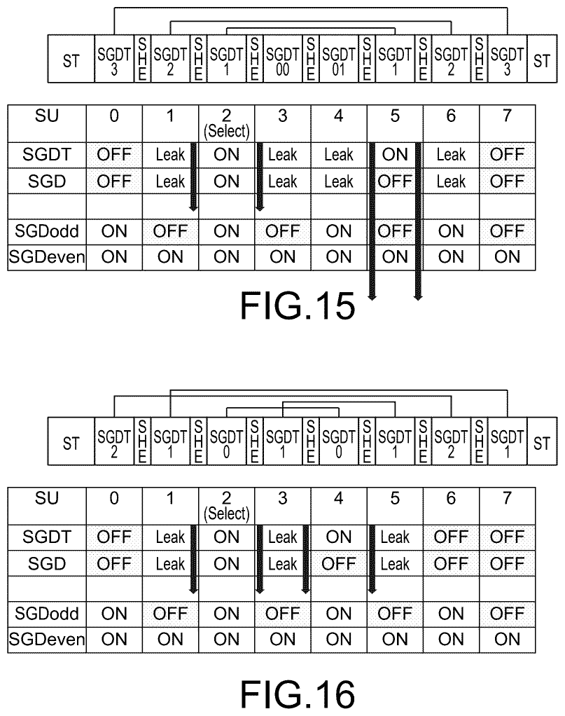

FIG. 15 is a schematic diagram illustrating a semiconductor storage device 200 according to a comparative example. In the example illustrated in FIG. 15, the semiconductor storage device 200 is configured to simultaneously apply the same voltage to each of pairs of drain-side select gate lines SGDT1, SGDT2, and SGDT3 that are paired so as to shorten the wiring length. In the example illustrated in FIG. 15, when the third string unit SU2 is selected, the selection voltage is applied at the same time to the drain-side select gate line SGDT1 of the sixth string unit SU5. Therefore, a leakage current is generated in the fifth string unit SU4 and the seventh string unit SU6 adjacent to the sixth string unit SU5.

Therefore, according to the second embodiment, it is possible to suppress a leakage current more effectively.

### Modification

FIG. 16 is a schematic diagram illustrating a semiconductor storage device 200 according to a modification of the second embodiment. In FIG. 14, the example in which the control to simultaneously apply the same voltage to the drain-side select gate lines SGDT0 of all the odd-numbered string units SU0, SU2, SU4, and SU6 and to simultaneously apply the same voltage to the drain-side select gate lines SGDT1 of all the even-numbered string units SU1, SU3, and SU5 in the same block is executed has been described. In contrast thereto, combinations of drain-side select gate lines SGDT to which the same voltage is simultaneously applied may be subdivided as illustrated in FIG. 16.

### Third Embodiment

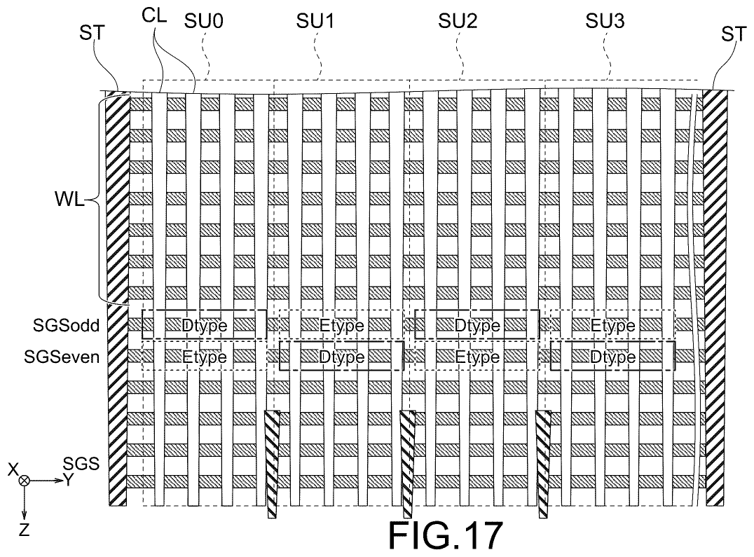

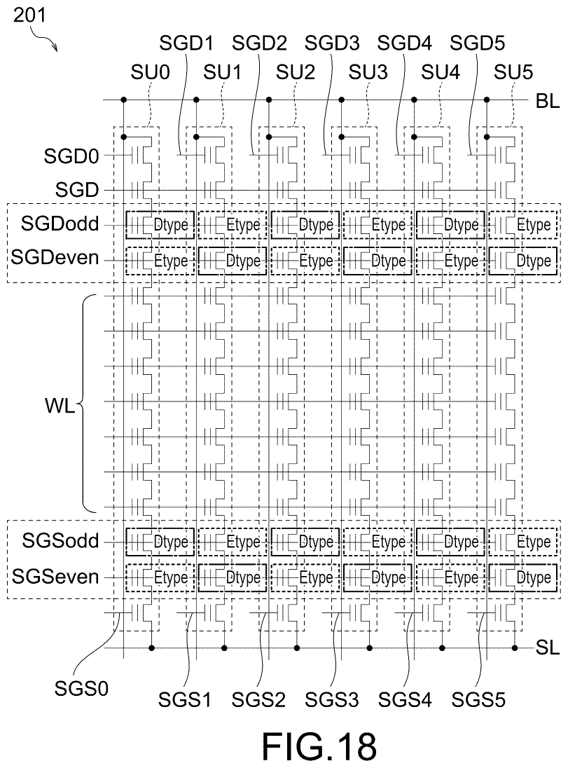

A third embodiment in which the source-side select gate lines are divided by the dividing portions SHE is described next focused on differences from the embodiments described above. FIG. 17 is a sectional view illustrating a memory cell array 201 of a single block in a semiconductor storage device 200 according to the third embodiment. FIG. 18 is a circuit diagram illustrating an equivalent circuit of the semiconductor storage device 200 according to the third embodiment.

The example in which the drain-side select gate lines are divided by the dividing portions SHE has been described above. In contrast thereto, the semiconductor storage device 200 according to the third embodiment further includes the dividing portions SHE that divide the source-side select gate lines SGS as illustrated in FIGS. 17 and 18. In FIG. 17, illustrations of the dividing portions SHE that divide the drain-side select gate lines SGD are omitted. The semiconductor storage device 200 according to the third embodiment includes one layer of a source-side select gate line SGSodd that is not divided by the dividing portions SHE and that selects the odd-numbered string units SU0, SU2, and SU4. The semiconductor storage device 200 according to the third embodiment includes one layer of a source-side select gate line SGSeven that is not divided by the dividing portions SHE and that selects the even-numbered string units SU1, SU3, and SU5.

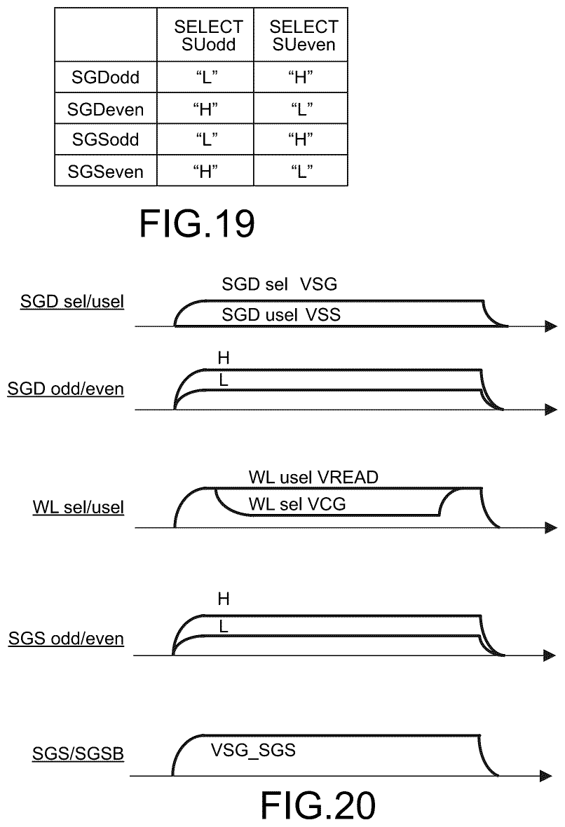

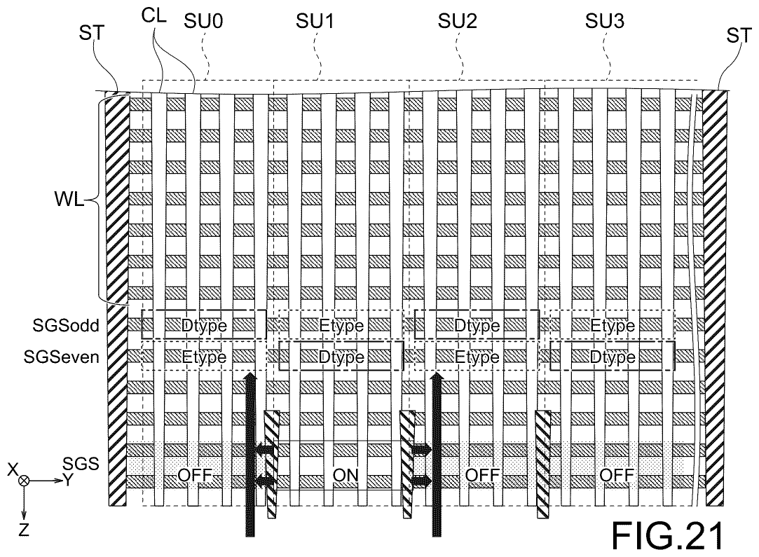

FIG. 19 is a table representing control on application of voltages to the select gate lines in an operation example of the semiconductor storage device 200 according to the third embodiment. The sequencer 205 applies voltages to the select gate lines in accordance with the table illustrated in FIG. 19. FIG. 20 is a waveform diagram illustrating an operation example of the semiconductor storage device 200 according to the third embodiment. Definitions of voltages illustrated in FIGS. 19 and 20 are substantially the same as those in the embodiments described above. FIG. 21 is a sectional view illustrating an operation example of the semiconductor storage device 200 according to the third embodiment.

According to the third embodiment, it is possible to suppress a leakage current from flowing from the dividing portions SHE into the even-numbered string units SU1, SU3, and SU5 when an odd-numbered string unit SU0, SU2, or SU4 is selected by the source-side select gate lines SGSodd and SGSeven. It is also possible to suppress a leakage current from flowing from the dividing portions SHE into the odd-numbered string units SU0, SU2, and SU4 when an even-numbered string unit SU1, SU3, or SU5 is selected.

In the example illustrated in FIG. 21, when the second string unit SU1 is selected, the voltage L of the first level is applied to the source-side select gate lines SGSeven of the first string units SU0 and the third string unit SU2. Accordingly, the select transistors Etype of the first string unit SU0 and the third string unit SU2 are turned off. With turning-off of the select transistors Etype, a leakage current represented by thick line arrows in FIG. 21 can be blocked.

Therefore, according to the third embodiment, similarly to the first embodiment, it is possible to suppress a leakage current caused by overlap of the dividing portions SHE with memory strings with a minimum necessary structure.

### Fourth Embodiment

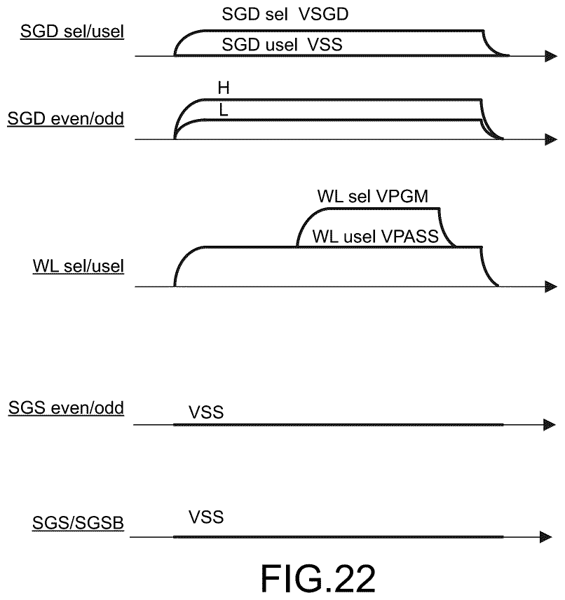

FIG. 22 is a waveform diagram illustrating an operation example of a semiconductor storage device 200 according to a fourth embodiment. The configuration of the semiconductor storage device 200 and the control on application of voltages described above are also applicable to a write operation illustrated in FIG. 22. In a write operation, the sequencer 205 applies a high voltage VPGM to a selected word line WLsel. Meanwhile, the sequencer 205 applies a voltage VPASS that is high enough to turn off a memory transistor and low enough to prevent writing to unselected word lines WLusel.

When a write operation for memory cells in an odd-numbered string unit SU0, SU2, or SU4 is to be performed, the sequencer 205 applies a selection voltage VSGD to the drain-side select gate line SGD of any one of the odd-numbered string units SU0, SU2, and SU4. The sequencer 205 also applies the non-selection voltage VSS to the drain-side select gate lines SGD of unselected odd-numbered string units SU0, SU2, or SU4.

When a write operation for memory cells in an odd-numbered string unit SU0, SU2, or SU4 is to be performed, the sequencer 205 applies the non-selection voltage VSS to the drain-side select gate lines SGD of the even-numbered string units SU1, SU3, and SU5.

When a write operation for memory cells in an odd-numbered string unit SU0, SU2, or SU4 is to be performed, the sequencer 205 applies the voltage L of the first level higher than the threshold voltage of the select transistors Dtype (that is, the first selection transistors) of the odd-numbered string units SU0, SU2, and SU4 and lower than the threshold voltage of the select transistors Etype (that is, the third selection transistors) of the even-numbered string units SU1, SU3, and SU5 to the drain-side select gate line SGDodd.

When a write operation for memory cells in an odd-numbered string unit SU0, SU2, or SU4 is to be performed, the sequencer 205 applies the voltage H of the second level higher than the threshold voltage of the select transistors Etype (that is, the second selection transistors) of the odd-numbered string units SU0, SU2, and SU4 and the threshold voltage of the select transistors Dtype (that is, the fourth selection transistors) of the even-numbered string units SU1, SU3, and SU5 to the drain-side select gate line SGDeven.

Meanwhile, when a write operation for memory cells in an even-numbered string unit SU1, SU3, or SU5 is to be performed, the sequencer 205 applies the selection voltage VSGD to the drain-side select gate line SGD of any one of the even-numbered string units SU1, SU3, and SU5. The sequencer 205 also applies the non-selection voltage VSS to the drain-side select gate lines SGD of unselected even-numbered string units SU1, SU3, or SU5.

When a write operation for memory cells in an even-numbered string unit SU1, SU3, or SU5 is to be performed, the sequencer 205 applies the non-selection voltage VSS to the drain-side select gate lines SGD of the odd-numbered string units SU0, SU2, and SU4.

When a write operation for memory cells in an even-numbered string unit SU1, SU3, or SU5 is to be performed, the sequencer 205 applies the voltage H of the second level higher than the threshold voltage of the select transistors Dtype (that is, the first selection transistors) of the odd-numbered string units SU0, SU2, and SU4 and the threshold voltage of the select transistors Etype (that is, the third selection transistors) of the even-numbered string units SU1, SU3, and SU5 to the drain-side select gate line SGDodd.

When a write operation for memory cells in an even-numbered string unit SU1, SU3, or SU5 is to be performed, the sequencer 205 applies the voltage L of the first level higher than the threshold voltage of the select transistors Dtype (that is, the fourth selection transistors) of the even-numbered string units SU1, SU3, and SU5 and lower than the threshold voltage of the select transistors Etype (that is, the second selection transistors) of the odd-numbered string units SU0, SU2, and SU4 to the drain-side select gate line SGDeven.

According to the fourth embodiment, it is also possible to suppress a leakage current in performing a write operation.

The control on application of the selection voltage described in the embodiments described above is also applicable to a verify operation for verifying whether the threshold voltage of a memory transistor has risen. Further, the configuration of suppressing a leakage current described in the embodiments described above is also applicable to a semiconductor storage device having a CUA (CMOS Under Array) structure.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a bit line;
a plurality of word lines stacked in a first direction to be spaced apart from each other;
a plurality of string units each comprising a memory string comprising a plurality of memory cells and a plurality of selection transistors connected in series in the first direction and the string units being adjacent to each other in a second direction;
a plurality of first selection gate lines divided from each other in the second direction;
a dividing portion partially overlapping one of the memory strings electrically connected to the bit line when seen from the first direction, and dividing the first selection gate lines from each other;
a second selection gate line not divided by the dividing portion and configured to select odd-numbered string units; and
a third selection gate line not divided by the dividing portion and configured to select even-numbered string units.

2. The device of claim 1, wherein the second selection gate line and the third selection gate line are arranged away in the first direction from the dividing portion.

3. The device of claim 1, wherein the first selection gate line, the second selection gate line, and the third selection gate line are drain-side selection gate lines.

4. The device of claim 1, wherein the first selection gate line, the second selection gate line, and the third selection gate line are source-side selection gate lines.

5. The device of claim 1, further comprising a plurality of fourth selection gate lines arranged in an upper layer than the first selection gate lines, divided by the dividing portion, and configured to generate a GIDL (gate induced drain leakage) current, wherein
a same voltage is simultaneously applied to the fourth selection gate lines corresponding to two or more of the odd-numbered string units among the fourth selection gate lines, and
a same voltage is simultaneously applied to the fourth selection gate lines corresponding to two or more of the even-numbered string units among the fourth selection gate lines.

6. The device of claim 1, wherein
each of the odd-numbered string units comprises a depletion-type first selection transistor selected by the second selection gate line, and an enhancement-type second selection transistor selected by the third selection gate line, and
each of the even-numbered string units comprises an enhancement-type third selection transistor selected by the second selection gate line, and a depletion-type fourth selection transistor selected by the third selection gate line.

7. The device of claim 6, further comprising a control circuit configured to control application of voltages to the first selection gate line, the second selection gate line, and the third selection gate line.

8. The device of claim 7, wherein the control circuit applies a selection voltage to any one of the first selection gate lines of the odd-numbered string units, applies a non-selection voltage to the first selection gate lines of ones of the odd-numbered string units to which the selection voltage has not been applied and to the first selection gate lines of the even-numbered string units, applies a voltage higher than a threshold voltage of the first selection transistors and lower than a threshold voltage of the third selection transistors to the second selection gate line, and applies a voltage higher than a threshold voltage of the second selection transistors and a threshold voltage of the fourth selection transistors to the third selection gate line, when a read operation for memory cells in the odd-numbered string units is to be performed.

9. The device of claim 7, wherein the control circuit applies a selection voltage to any one of the first selection gate lines of the even-numbered string units, applies a non-selection voltage to the first selection gate lines of ones of the even-numbered string units to which the selection voltage has not been applied and to the first selection gate lines of the odd-numbered string units, applies a voltage higher than a threshold voltage of the first selection transistors and a threshold voltage of the third selection transistors to the second selection gate line, and applies a voltage higher than a threshold voltage of the fourth selection transistors and lower than a threshold voltage of the second selection transistors to the third selection gate line, when a read operation for memory cells in the even-numbered string units is to be performed.

10. The device of claim 7, wherein the control circuit applies a selection voltage to any one of the first selection gate lines of the odd-numbered string units, applies a non-selection voltage to the first selection gate lines of ones of the odd-numbered string units to which the selection voltage has not been applied and to the first selection gate lines of the even-numbered string units, applies a voltage higher than a threshold voltage of the first selection transistors and lower than a threshold voltage of the third selection transistors to the second selection gate line, and applies a voltage higher than a threshold voltage of the second selection transistors and a threshold voltage of the fourth selection transistors to the third selection gate line, when a write operation for memory cells in the odd-numbered string units is to be performed.

11. The device of claim 7, wherein the control circuit applies a selection voltage to any one of the first selection gate lines of the even-numbered string units, applies a non-selection voltage to the first selection gate lines of ones of the even-numbered string units to which the selection voltage has not been applied and to the first selection gate lines of the odd-numbered string units, applies a voltage higher than a threshold voltage of the first selection transistors and a threshold voltage of the third selection transistors to the second selection gate line, and applies a voltage higher than a threshold voltage of the fourth selection transistors and lower than a threshold voltage of the second selection transistors to the third selection gate line, when a write operation for memory cells in the even-numbered string units is to be performed.

12. The device of claim 8, further comprising a fifth selection gate line arranged on an opposite side of the word lines to the first selection gate lines, the second selection gate line, and the third selection gate line, wherein
each of the odd-numbered string units further comprises a fifth selection transistor selected by the fifth selection gate line,
each of the even-numbered string units further comprises a sixth selection transistor selected by the fifth selection gate line, and
the control circuit applies a voltage for turning on the fifth selection transistor and turning off the sixth selection transistor to the fifth selection gate line when a read operation and a write operation for memory cells in the odd-numbered string units are to be performed, and applies a voltage for turning on the sixth selection transistor and turning off the fifth selection transistor to the fifth selection gate line when a read operation and a write operation for memory cells in the even-numbered string units are to be performed.

13. The device of claim 1, wherein
each of the odd-numbered string units comprises an enhancement-type seventh selection transistor selected by the second selection gate line, and a depletion-type eighth selection transistor selected by the third selection gate line, and
each of the even-numbered string units comprises a depletion-type ninth selection transistor selected by the second selection gate line, and an enhancement-type tenth selection transistor selected by the third selection gate line.

14. The device of claim 13, further comprising a second control circuit configured to control application of voltages to the first selection gate lines, the second selection gate line, and the third selection gate line.

15. The device of claim 14, wherein the second control circuit applies a selection voltage to any one of the first selection gate lines of the odd-numbered string units, applies a non-selection voltage to the first selection gate lines of ones of the odd-numbered string units to which the selection voltage has not been applied and to the first selection gate lines of the even-numbered string units, applies a voltage higher than a threshold voltage of the seventh selection transistors and a threshold voltage of the ninth selection transistors to the second selection gate line, and applies a voltage higher than a threshold voltage of the eighth selection transistors and lower than a threshold voltage of the tenth selection transistors to the third selection gate line, when a read operation for memory cells in the odd-numbered string units is to be performed.

16. The device of claim 14, wherein the second control circuit applies a selection voltage to any one of the first selection gate lines of the even-numbered string units, applies a non-selection voltage to the first selection gate lines of ones of the even-numbered string units to which the selection voltage has not been applied and to the first selection gate lines of the odd-numbered string units, applies a voltage higher than a threshold voltage of the ninth selection transistors and lower than a threshold voltage of the seventh selection transistors to the second selection gate line, and applies a voltage higher than a threshold voltage of the tenth selection transistors and a threshold voltage of the eighth selection transistors to the third selection gate line, when a read operation for memory cells in the even-numbered string units is to be performed.

17. The device of claim 14, wherein the second control circuit applies a selection voltage to any one of the first selection gate lines of the odd-numbered string units, applies a non-selection voltage to the first selection gate lines of ones of the odd-numbered string units to which the selection voltage has not been applied and to the first selection gate lines of the even-numbered string units, applies a voltage higher than a threshold voltage of the seventh selection transistors and a threshold voltage of the ninth selection transistors to the second selection gate line, and applies a voltage higher than a threshold voltage of the eighth selection transistors and lower than a threshold voltage of the tenth selection transistors to the third selection gate line, when a write operation for memory cells in the odd-numbered string units is to be performed.

18. The device of claim 14, wherein the second control circuit applies a selection voltage to any one of the first selection gate lines of the even-numbered string units, applies a non-selection voltage to the first selection gate lines of ones of the even-numbered string units to which the selection voltage has not been applied and to the first selection gate lines of the odd-numbered string units, applies a voltage higher than a threshold voltage of the ninth selection transistors and lower than a threshold voltage of the seventh selection transistors to the second selection gate line, and applies a voltage higher than a threshold voltage of the tenth selection transistors and a threshold voltage of the eighth selection transistors to the third selection gate line, when a write operation for memory cells in the even-numbered string units is to be performed.

19. The device of claim 15, further comprising a sixth selection gate line arranged on an opposite side of the word lines to the first selection gate lines, the second selection gate line, and the third selection gate line, wherein
each of the odd-numbered string units further comprises an eleventh selection transistor selected by the sixth selection gate line,
each of the even-numbered string units further comprises a twelfth selection transistor selected by the sixth selection gate line, and
the second control circuit applies a voltage for turning on the eleventh selection transistor and turning off the twelfth selection transistor to the sixth selection gate line when a read operation and a write operation for memory cells in the odd-numbered string units are to be performed, and applies a voltage for turning on the twelfth selection transistor and turning off the eleventh selection transistor to the sixth selection gate line when a read operation and a write operation for memory cells in the even-numbered string units are to be performed.
